(19) United States
(12) Patent Application Publication
(10) Pub. No.: US 2019/0294009 A1
(43) Pub. Date: Sep. 26, 2019

(54) POLARIZED LIGHT RADIATION DEVICE AND POLARIZED LIGHT RADIATION METHOD

(71) Applicant: V TECHNOLOGY CO., LTD., Kanagawa (JP)

(72) Inventors: Toshinari ARAI, Kanagawa (JP); Takuro TAKESHITA, Kanagawa (JP)

(21) Appl. No.: 16/435,443

(22) Filed: Jun. 7, 2019

Related U.S. Application Data
(63) Continuation of application No. PCT/JP2018/001071, filed on Jan. 16, 2018.

(30) Foreign Application Priority Data
Jan. 26, 2017 (JP) 2017-011797

(51) Int. Cl. G02F 1/1337; G03F 7/20

(52) U.S. Cl. CPC G02F 1/133788; G03F 7/70141

(57) ABSTRACT

Polarized light emitted from a light source and transmitted through a light transmission region formed in a mask is radiated onto an exposure target object placed on a stage. The polarized light is radiated onto the exposure target object from a direction inclined by approximately 50° to approximately 70° in relation to a direction that is substantially orthogonal to a top surface of the stage.

### CROSS-REFERENCE TO RELATED APPLICATIONS

This application is a continuation application of International Patent Application No. PCT/JP2018/001071 filed on Jan. 16, 2018, which claims priority to Japanese Patent Application No. 2017-011797 filed on Jan. 26, 2017, the entire contents of which are incorporated by reference.

### TECHNICAL FIELD

The present invention relates to a polarized light radiation device and a polarized light radiation method.

### BACKGROUND ART

Patent Document 1 discloses a liquid crystal display apparatus including: a vertical alignment liquid crystal layer; a first substrate and a second substrate each of which has a light blocking member; a first electrode provided on a liquid crystal layer side of the first substrate and a second electrode provided on a liquid crystal layer side of the second substrate; and at least one alignment film in contact with the liquid crystal layer.

### CITATION LIST

### Patent Document

Patent Document 1: JP 2011-53721 A

FIG. 11 is a diagram illustrating an exemplar pixel region of the liquid crystal display apparatus using the vertical alignment liquid crystal layer described in Patent Document 1 (hereinafter referred to as a VA mode liquid crystal display apparatus). A pixel region 100 includes four liquid crystal domains A, B, C, and D. Assuming that the 3 o'clock direction in the figure is 0°, the tilt directions t1, t2, t3, and t4 of the liquid crystal domains A, B, C, and D are 225°, 315°, 45°, 135°, respectively. In this way, by dividing each single pixel into a plurality of regions, the viewing angle characteristics are improved.

However, the alignment of the liquid crystal molecules is disturbed at the boundary portion of the liquid crystal domain. The regions where the alignment of the liquid crystal molecules becomes discontinuous are visually recognized as dark lines because they do not transmit light. In the pixel region 100, dark lines (domain lines DL1, DL2, DL3, and DL4) along the edge portion are formed respectively in the liquid crystal domains A, B, C, and D.

FIGS. 12A and 12B are diagrams describing a method of dividing the pixel area 100. FIG. 12A illustrates a pre-tilt direction of an alignment film of a TFT substrate (lower substrate) 100a, and FIG. 12B illustrates a pre-tilt direction of the color filter substrate (upper substrate) 100b. The cylinders in FIGS. 12A and 12B schematically illustrate liquid crystal molecules. When the pixel region 100 using the TFT substrate 100a and the color filter substrate 100b are viewed from the observer side, the liquid crystal molecules are tilted so that the ends (elliptical portions) of the liquid crystal molecules shown in the cylindrical shape approach the observer.

The pixel region of the lower substrate is divided into two, and the pre-tilt directions PA1 and PA2 that are antiparallel to the vertical alignment film are given. In addition, the pixel region of the upper substrate is divided into two, and a pre-tilt directions PB1 and PB2 that are antiparallel to the vertical alignment film are given. By affixing the lower substrate and the upper substrate together, an alignment split structure of the pixel area 100 is obtained.

Patent Document 1 describes that a photoalignment process is performed by obliquely irradiating ultraviolet light from the direction indicated by the arrow in FIGS. 12A and 12B to define a pre-tilt direction of liquid crystal molecules in the alignment film. Patent Document 1 describes that it is preferable to have a small pre-tilt angle.

However, Patent Document 1 discloses no specific method for reducing the pre-tilt angle in a case where the photoalignment process is used to define the pre-tilt direction of the liquid crystal molecules in the alignment film.

### SUMMARY OF INVENTION

One or more embodiments of the present invention provide a polarized light radiation device and a polarized light radiation method capable of generating an alignment film having a small pre-tilt angle of liquid crystal molecules by a photoalignment process.

In one or more embodiments of the present invention, a polarized light radiation device includes, for example: a light source configured to emit polarized light; a mask where a light transmission region allowing polarized light having been emitted from the light source to pass therethrough is formed; and a stage on which an exposure target object to be irradiated with polarized light having passed through the light transmission region is placed. In the polarized light radiation device, the light source radiates polarized light onto the exposure target object from a direction inclined by approximately 50° to approximately 70° in relation to a direction that is substantially orthogonal to a top surface of the stage.

The polarized light radiation device according to one or more embodiments of the present invention radiates polarized light to the exposure target object from a direction inclined approximately 50° to approximately 70° in relation to a direction substantially orthogonal to a top surface of the stage. As a result, the alignment film can be produced by the photoalignment process so that the pre-tilt angle of the liquid crystal molecules becomes smaller. By generating a liquid crystal display apparatus using the alignment film generated in this manner, the dark lines that appear in the pixel region become narrower and a higher display quality is obtained.

The above-described polarized light radiation device may further include a drive unit configured to move the stage in a transport direction and rotate the stage by approximately 180°. In the polarized light radiation device, the light source may include a first light source and a second light source that are arranged along the transport direction. The drive unit may be configured to rotate the stage by approximately 180° between the first light source and the second light source. The mask may include: a first mask having a first light transmission region formed therein, the first light transmission region allowing exposure light having been emitted from the first light source to pass therethrough; and a second mask having a second light transmission region formed therein, the second light transmission region allowing exposure light having been emitted from the second light source to pass therethrough. The second light transmission region may be formed at a position to allow light to be radiated onto a region in the exposure target object, the region being not irradiated with any light having passed through the first light transmission region. The above-described configuration allows polarized light to be radiated to different positions of the same exposure target object from different directions.

One or more embodiments of the present invention provides a polarized light radiation method. The method includes the step of, for example, emitting light from a direction inclined by approximately 50° to approximately 70° in relation to a direction that is substantially orthogonal to a top surface of a stage on which an exposure target object is placed, the light being emitted while the stage being transported in a transport direction.

One or more embodiments of the present invention provides a polarized light radiation method. The method includes the steps of: transporting, in a transport direction, a stage on which an exposure target object is placed; with the stage having been transported to a first position, emitting light from a direction inclined by approximately 50° to approximately 70° in relation to a direction that is substantially orthogonal to a top surface of the stage and radiating the light onto a first region of the exposure target object while the stage is being transported in the transport direction; transporting the stage in the transport direction to a second position; with the stage having been transported to the second position, rotating the stage by approximately 180°; transporting the stage in the transport direction to a third position; and with the stage having been transported to the third position, emitting light from a direction inclined by approximately 50° to approximately 70° in relation to a direction that is substantially orthogonal to the top surface of the stage and radiating the light onto a second region of the exposure target object while the stage is being transported in the transport direction, the second region being different from the first region.

According to one or more embodiments of the present invention, an alignment film can be produced by the photoalignment process so that the pre-tilt angle of the liquid crystal molecules becomes smaller.

### BRIEF DESCRIPTION OF DRAWINGS

FIG. 1 is a schematic perspective view of a polarized light radiation device 1 according to a first embodiment.

FIG. 2 is a schematic front view illustrating the polarized light radiation device 1 with a portion thereof enlarged.

FIG. 3 is a diagram illustrating a light transmission region formed in a mask 32, and is a schematic view of the mask 32 when viewed in plan view.

FIG. 4 is a block diagram illustrating an electrical configuration of the polarized light radiation device 1.

FIG. 5 is a diagram schematically illustrating positions in the substrates W1, W2, and W3 in the light-irradiated region EA1, the positions being ones at which polarized light is radiated.

FIG. 6 is a diagram describing positions in the substrates W1, W2, and W3 in the light-irradiated region EA2, the positions being the ones at which polarized light is radiated.

FIG. 7 is a graph illustrating a relationship between a reflectivity of P-polarized light and an incident angle θ1.

FIG. 8 is a graph showing a relationship between the Brewster's angle and the refractive index.

FIG. 9 is a schematic front view of a polarized light radiation device 2 according to a second embodiment.

FIG. 10 is a diagram illustrating a light transmission region formed in a mask 33.

FIG. 11 is a diagram illustrating an exemplar pixel region of a liquid crystal display apparatus using a vertically oriented liquid crystal layer (VA mode liquid crystal display apparatus) described in Patent Document 1.

FIGS. 12A and 12B are diagrams describing a method of dividing the pixel area 100. FIG. 12A illustrates a pre-tilt direction of an alignment film of a TFT substrate 100a, and FIG. 12B illustrates a pre-tilt direction of the color filter substrate 100b.

### DESCRIPTION OF EMBODIMENTS

Below, detailed description of embodiments of the present invention will be given with reference to drawings.

### First Embodiment

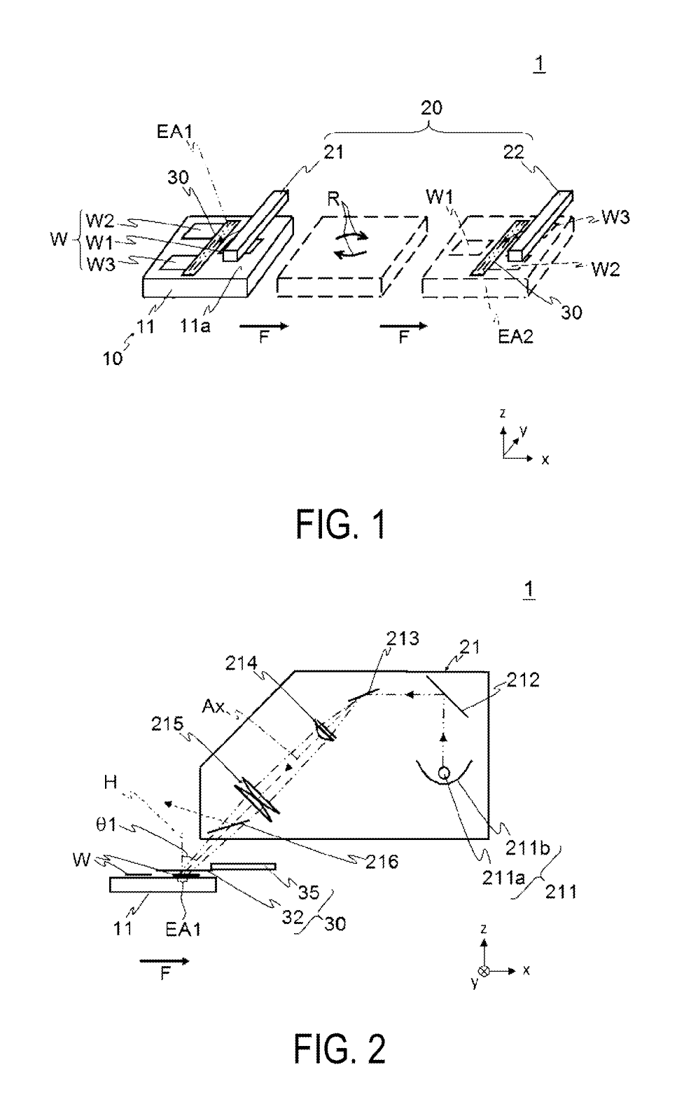

FIG. 1 is a schematic perspective view of a polarized light radiation device 1 according to a first embodiment. The polarized light radiation device 1 is, for example, a device that produces an alignment film such as a liquid crystal panel by performing a photoalignment process by radiating the surface to be exposed of a substrate W (for example, a glass substrate), which is an object to be exposed (hereinafter, referred to as the “exposure target object”). The substrate W is, for example, a glass substrate having an alignment material film formed on a surface thereof. The photoalignment process is a process to give anisotropy to a film by radiating linearly polarized ultraviolet light onto a polymeric film to induce a rearrangement or an anisotropic chemical reaction of molecules within the film.

Hereinafter, a transport direction (i.e., the scanning direction) F of the substrate W is referred to as the x direction, a direction orthogonal to the transport direction F is referred to as the y direction, and the vertical direction is referred to as the z direction.

The polarized light radiation device 1 includes mainly a transport unit 10 configured to transport the substrate W, a light radiation unit 20 configured to emit exposure light, and a mask unit 30.

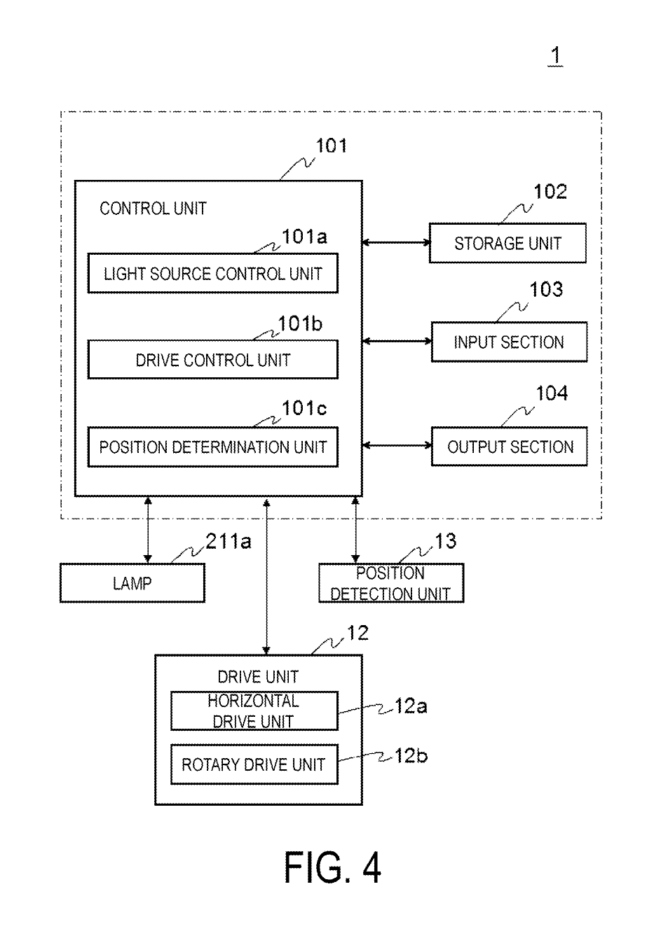

The transport unit 10 mainly includes a stage 11, a drive unit 12 configured to drive the stage 11 (see FIG. 4), and a position detection unit 13 configured to measure the position of the stage 11 (see FIG. 4).

The substrate W is placed on a top surface 11a of the stage 11. In the present embodiment, three substrates W (i.e., the substrate W is a concept including substrates W1, W2, and W3) are disposed in a staggered manner.

The drive unit 12 includes a horizontal drive unit 12a configured to move the stage 11 in the horizontal direction (see FIG. 4), and a rotary drive unit 12b configured to rotate the stage 11 (see FIG. 4). The horizontal drive unit 12a includes an actuator (not illustrated) and a drive mechanism, and is configured to move the stage 11 along the transport direction F. The rotary drive unit 12b includes an actuator (not illustrated) and a drive mechanism (not illustrated), and is configured to rotate the stage 11 by approximately 180°. The stage 11 is rotated by approximately 180° between a light radiation unit 21 (described in detail later) and a light radiation unit 22 (described in detail later) by the rotary drive unit 12b.

The position detection unit 13 is, for example, a sensor or a camera. When the stage 11 moves in the transport direction F, the position of the stage 11 is detected by the position detection unit 13.

The light radiation unit 20 is configured to radiate light onto the substrate W. The light radiation unit 20 mainly includes two light radiation units 21 and 22 provided along the x direction.

FIG. 2 is a schematic front view illustrating the polarized light radiation device 1 with a portion thereof enlarged. FIG. 2 provides a see-through image of a main part of the light radiation unit 21. Since the light radiation unit 21 and the light irradiating unit 22 have an identical configuration, description of the light radiation unit 22 will be omitted.

The light radiation unit 21 mainly includes a light source 211, mirrors 212 and 213, a fly-eye lens 214, a condenser lens 215, and a polarizing beam splitter (PBS) 216.

The light source 211 mainly includes a lamp 211a and a reflective mirror 211b provided on a back side of the lamp 211a. The lamp 211a is, for example, a mercury lamp, and is configured to emit unpolarized light (e.g., ultraviolet light). Note that a xenon lamp, an excimer lamp, an ultraviolet LED, or the like may also be used as the lamp 211a. The reflective mirror 211b is, for example, an elliptical reflective mirror, and is configured to reflect light of the lamp 211a forward.

The light emitted from the lamp 211a is reflected by the reflective mirror 211b and is redirected by the mirrors 212 and 213. Consequently, the resultant light is led to the fly-eye lens 214. The two-dot chain lines in FIG. 2 indicate the paths of the light, and the arrows indicate the traveling directions of the light.

The fly-eye lens 214 is a lens in which a plurality of small lenses are disposed in a staggered manner, and makes the irradiation surface have a uniform illuminance distribution.

The condenser lens 215 is formed by assembling a plurality of lenses, and is a lens configured to concentrate light. Light passed through the fly-eye lens 214 is concentrated by the condenser lens 215 and is led to PBS 216.

PBS 216 is an optical element configured to split incident light into S-polarized light and P-polarized light by reflecting the S-polarized light (see dotted-line arrow in FIG. 2) and transmitting the P-polarized light.

The light radiation unit 21 is configured to radiate the polarized light onto the substrate W from a direction inclined by approximately 50° to approximately 70° in relation to a direction substantially orthogonal to the top surface 11a of the stage 11 (i.e., substantially orthogonal to the z direction). To put it differently, the light radiation unit 21 (in particular, the mirror 213, the fly-eye lens 214, the condenser lens 215, and the PBS 216) are provided so that the incident angle of the P-polarized light θ1 (the angle formed by the central axis Ax of the light and the line H extending along the z direction) ranges from approximately 50° to approximately 70°. The incident angle θ1 will be described in detail later.

The mask unit 30 is provided on an optical path of the polarized light radiated from the light radiation units 21 and 22 to the substrate W. When the polarized light is radiated from the light radiation units 21 and 22 to the substrate W, the mask unit 30 and the top surface 11a are adjacent to each other.

The mask unit 30 mainly includes a mask 32 and a mask holding unit 35. The mask 32 is a substantially plate-like member, and has a substantially rectangular shape in plan view. The mask 32 is held substantially parallel to the top surface 11a by the mask holding unit 35. In addition, the mask 32 is driven in the x direction, the y direction, the z direction, and the θ direction by the mask holding unit 35.

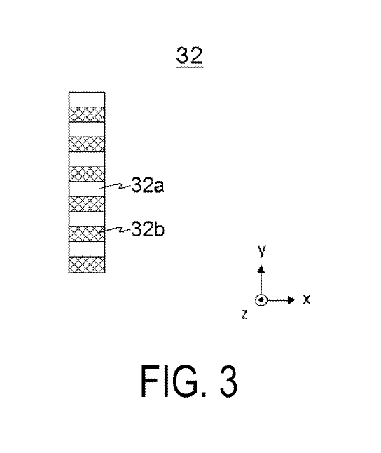

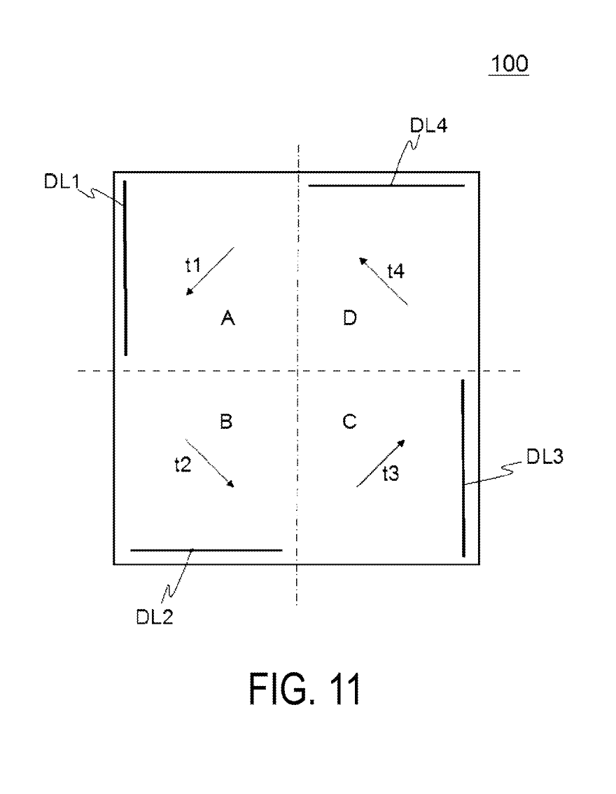

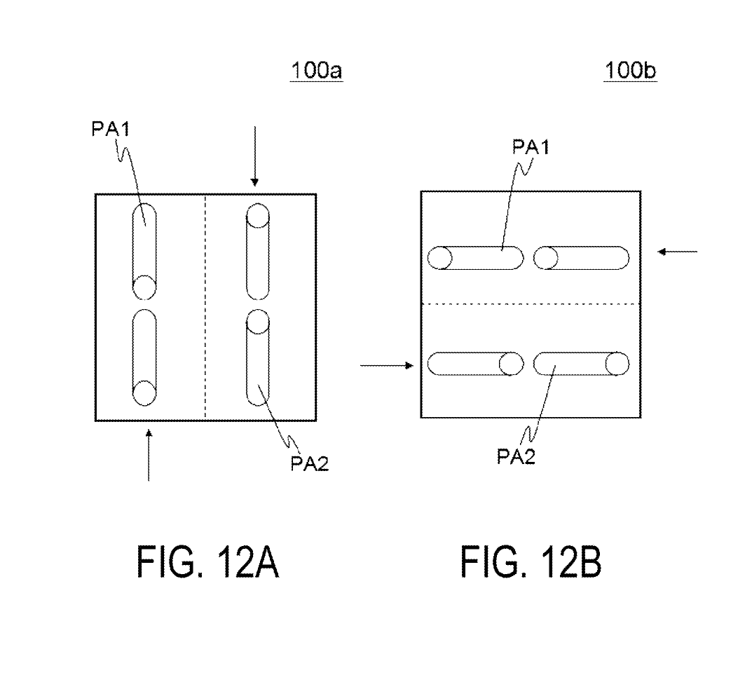

FIG. 3 is a diagram illustrating a light transmission region formed in the mask 32, and is a schematic view of the mask 32 when viewed in plan view. The mask 32 includes band-like light transmission regions 32a each of which extends in the x direction. In addition, the mask 32 band-shaped light blocking regions 32b each of which extends in the x direction. The light transmissive regions 32a have a width that is half the width of the pixel area 100 and so do the light blocking regions 32b (see FIG. 11, etc.). The light transmission regions 32a and the light blocking regions 32b alternate in a direction (specifically, in the y direction) that is substantially orthogonal to the x direction. The P-polarized light that has passed through the PBS 216 passes through the light transmission region 32a, and is radiated onto the substrate W.

FIG. 4 is a block diagram illustrating an electrical configuration of the polarized light radiation device 1. The polarized light radiation device 1 mainly includes a control unit 101, a storage unit 102, an input section 103, and an output section 104.

The control unit 101 is a program control device such as a Central Processing Unit (CPU), which is an arithmetic unit. The control unit 101 is configured to operate in accordance with a program stored in the storage unit 102. In the present embodiment, the control unit 101 is configured to function as: a light source control unit 101a configured to control the lighting up and off of the lamp 211a; a drive control unit 101b configured to control the drive unit 12 to move or rotate the stage 11; a position determination unit 101c configured to acquire measurement results from the position detection unit 13 and thus to determine the position of the stage 11 and the position of the substrate W placed on the stage 11. Note that the techniques for moving and positioning the stage 11 are already publicly known techniques, and thus descriptions thereof will be omitted. Details of the operation of the control unit 101 will be described in detail later.

The storage unit 102 is a volatile memory, a non-volatile memory, or the like. The storage unit 102 holds, among other things, programs to be executed by the control unit 101, and operates as a working memory for the control unit 101.

The input section 103 includes an input device such as a keyboard or a mouse. The output section 104 is a display or the like.

Next, the operations of the polarized light radiation device 1 configured as described above will be described with reference to FIG. 1. The drive control unit 101b makes the horizontal drive unit 12a move the stage 11 along the transport direction F (in the +x direction). The substrate W1 is disposed on the top surface 11a, specifically on the downstream side (+x side) thereof in the transport direction F. In addition, the substrates W2 and W3 are disposed on the upstream side (−x side) thereof in the transport direction F.

When the position determination unit 101c determines that the substrate W1 is about to enter a region to be irradiated with the P-polarized light from the light radiation unit 21 (i.e., light-irradiated region EA1), the light source control unit 101a turns on the lamp 211a of the light radiation unit 21. Then, with the lamp 211a kept in that state, the drive control unit 101b moves the stage 11 in the transport direction F. As a result, the light radiated by the light radiation unit 21 is continuously radiated onto the substrate W. Of the P-polarized light from the light radiation unit 21, the light that has passed through the light transmission region 32a is first radiated onto the substrate W1, and is then radiated onto the substrates W2 and W3.

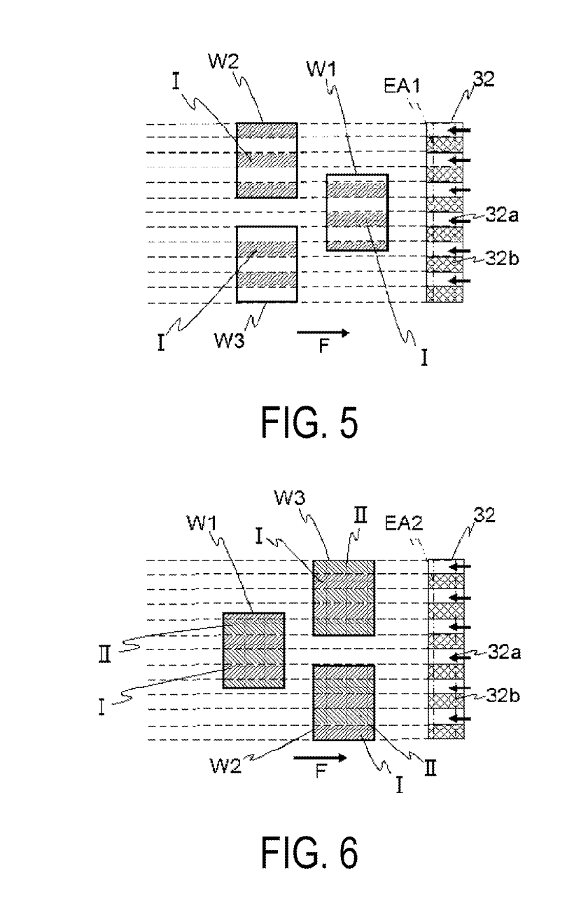

FIG. 5 is a diagram schematically illustrating positions in the substrates W1, W2, and W3 in the light-irradiated region EA1, the positions being ones at which polarized light is radiated. In FIG. 5, for the purposes of illustration, the mask 32 (the light transmission region 32a and the light blocking region 32b) and the light-irradiated region EA1 are illustrated side-by-side with the substrates W1, W2, and W3. In addition, the thick arrows in FIG. 5 schematically represent the irradiation by the polarized light.

The polarized light that has passed through the light transmission region 32a is radiated onto regions I (shaded by upward diagonal lines in FIG. 5) in the substrates W1, W2, and W3. The regions I are band-like regions extending along the transport direction F.

The description will now return to FIG. 1. When the position determination unit 101c determines that the substrates W2 and W3 have traveled past the light-irradiated region EA1, the light source control unit 101a turns off the lamp 211a of the light radiation unit 21. Then, with the lamp 211a kept in that state, the drive control unit 101b moves the stage 11 in the transport direction F.

When the position determining unit 101c determines that the current position of the stage 11 is between the light radiation unit 21 and the light radiation unit 22, the drive control unit 101b makes the rotary drive unit 12b rotate the stage 11 by approximately 180° (see arrows R in FIG. 1). Hence, on the top surface 11a, the substrates W2 and W3 are positioned on the +x side, and the substrate W1 is positioned on the −x side.

After the stage 11 has been rotated, the drive control unit 101b moves the stage 11 in the transport direction F. When the position determination unit 101c determines that the substrate W2 and W3 are about to enter a region to be irradiated with the P-polarized light from the light radiation unit 22 (i.e., light-irradiated region EA2), the light source control unit 101a turns on the lamp 211a of the light radiation unit 22. Then, with the lamp 211a kept in that state, the drive control unit 101b moves the stage 11 in the transport direction F. As a result, the light radiated by the light radiation unit 22 is continuously radiated onto the substrate W. Of the P-polarized light from the light radiation unit 22, the light that has passed through the light transmission region 32a is first radiated onto the substrates W2 and W3, and is then radiated onto the substrate W1.

FIG. 6 is a diagram describing positions in the substrates W1, W2, and W3 in the light-irradiated region EA2, the positions being the ones at which polarized light is radiated. In FIG. 6, for the purposes of illustration, the mask 32 (the light transmission region 32a and the light blocking region 32b) and the light-irradiated region EA2 are illustrated side-by-side with the substrates W1, W2, and W3. In addition, the thick arrows in FIG. 6 schematically represent the irradiation by the polarized light.

The polarized light that has passed through the light transmission region 32a is radiated onto regions II (shaded by downward diagonal lines in FIG. 6) in the substrates W1, W2, and W3. The regions II are band-like regions extending along the transport direction F. The regions I and II are formed alternately along the y direction. Once the regions I and II have been formed, the control unit 101 terminates the series of processes.

Now, the point in which the incident angle θ1 of the P-polarized light having passed through the PBS 216 is made to range from approximately 50° to approximately 70° will be described in detail.

The dark lines generated to extend along the edge portions in the pixel region 100 (see FIG. 11 and the like) become narrower as the pre-tilt angle (the average inclination angle of the liquid crystal molecules in relation to the surface of the substrate W) decreases. In a case where the pre-tilt direction of the liquid crystal molecules in the alignment film is defined through the photoalignment process, an increase in the incident angle θ1 results in a decrease in the pre-tilt angle. Hence, it is desirable that the incident angle θ1 be as large as possible.

An excessively large incident angle θ1, however, results in a large reflectivity of the P-polarized light. Even in a case where the substrate W is irradiated with P-polarized light, a large reflectivity makes the absorption of light by the substrate W more difficult.

Hence, it is desirable that the incident angle θ1 be as large as possible as long as the reflectivity can be kept low enough.

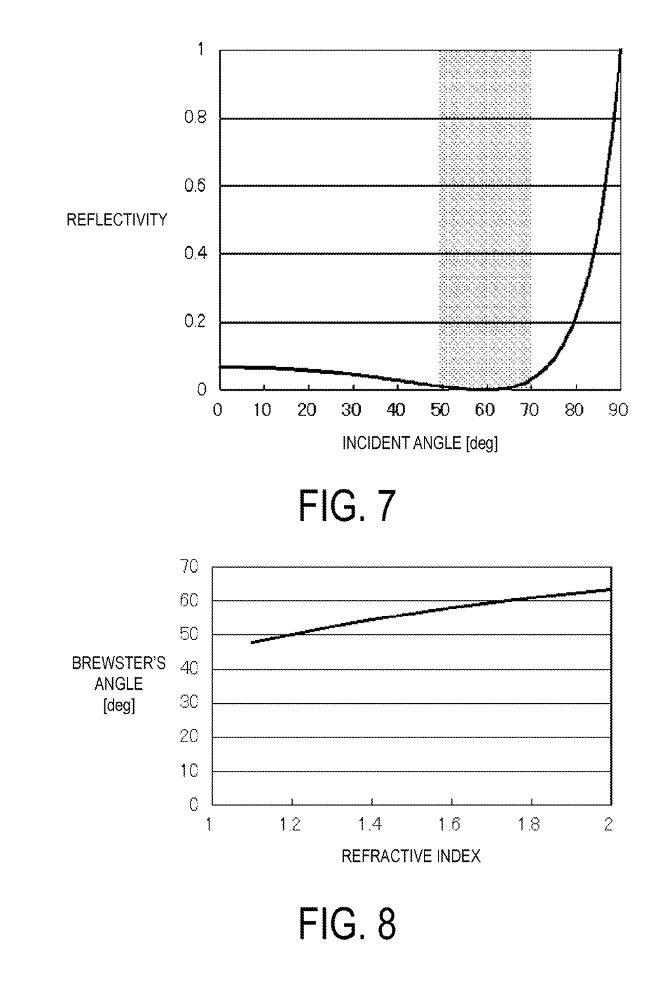

FIG. 7 is a graph illustrating a relationship between a reflectivity of P-polarized light and an incident angle θ1. In the example illustrated in FIG. 7, the substrate W has a refractive index of 1.7 in a case where light having traveled in the air enters the substrate W.

With a refractive index of 1.7, an incident angle (Brewster's angle) of approximately 59.5° results in an approximately zero reflectivity for the P-polarized light at the interface between the air and the substrate W. Hence, to satisfy the conditions that the incident angle θ1 needs to be as large as possible but that the reflectivity is kept low enough, the incident angle θ1 ranges from approximately 50° to approximately 70° (see the hatched portion in FIG. 7). While the range from approximately 50° to approximately 70° is centered on the angle of approximately 60°, which is a Brewster angle, the range results in a reflectivity that is not greater than the reflectivity of a case where the incident angle θ1 is approximately 40° (i.e., a typical incident angle θ1).

FIG. 8 is a graph showing a relationship between the Brewster's angle and the refractive index. Though an increase in the refractive index increases the Brewster's angle, the refractive index near 1.7 results in a slower changing rate in the Brewster's angle. Hence, the Brewster's angle of a case where the refractive index ranges from approximately 1.6 to approximately 1.8 can be considered more or less the same as the Brewster's angle of a case where the refractive index is 1.7 as illustrated in FIG. 7.

According to the present embodiment, setting the incident angle θ1 to an angle from approximately 50° to approximately 70° allows an alignment film to be produced through a photoalignment process so that the liquid crystal molecules have a small pre-tilt angle.

In addition, according to the present embodiment, polarized light radiation twice is performed during a single processing and the stage 11 is rotated by approximately 180° between the two events of the polarized light radiation. Hence, a single substrate can be irradiated with the polarized light at different positions thereof from different directions.

Note that in the present embodiment, the incident angle θ1 ranges from approximately 50° to approximately 70°, but the incident angle θ1 may be within a range from approximately 53° to approximately 65° though such an incident angle θ1 results in reflectivity within a lower range (the reflectivity being within a range from 0.01 or lower for a refractive index of 1.7).

In addition, in the present embodiment, a small pre-tilt angle of the liquid crystal molecules is achieved by setting the incident angle θ1 to an angle from approximately 50° to approximately 70°. A small pre-tilt angle of the liquid crystal molecules, however, can also be achieved by increasing the integral of the light with which the substrate W is irradiated. Hence, setting the incident angle θ1 to a value ranging from approximately 50° to approximately 70° and increasing the integral of the light by, for example, extending the output time of the lamp 211a and/or extending the exposure time (by transporting the stage 11 at a slower speed) can be another effective way of achieving a small pre-tilt angle of the liquid crystal molecules.

In addition, in the present embodiment, the regions I and II formed in the substrate W are contiguous to one other, but the regions I and II does not have to be contiguous to one another. For example, there may be a gap between one region I and a neighboring region II. In addition, in the present embodiment, both the polarized light emitted from the light radiation unit 21 and the polarized light emitted from the light radiation unit 22 pass through the light transmission region 32a formed in the mask 32. However, a different configuration is possible in some forms of the regions I and II. Specifically, the polarized light emitted from the light radiation unit 21 passes through a light transmission region formed at a position in the mask while the polarized light emitted from the light radiation unit 22 passes through the light transmission region formed at a different position in the mask.

### Second Embodiment

In the first embodiment, the regions I and II having different pre-tilt directions from each other are formed on the substrate W by rotating the stage 11 between the events of exposure, but this is not the only method of forming the regions I and II on the substrate W.

The second embodiment is an embodiment where the stage 11 is not rotated and where the regions I and II are formed substantially simultaneously on the substrate W. Now, a polarized light radiation device 2 according to the second embodiment will be described. Note that the same components as those of the polarized light radiation device 1 according to the first embodiment are denoted by the same reference numerals, and descriptions thereof will be omitted.

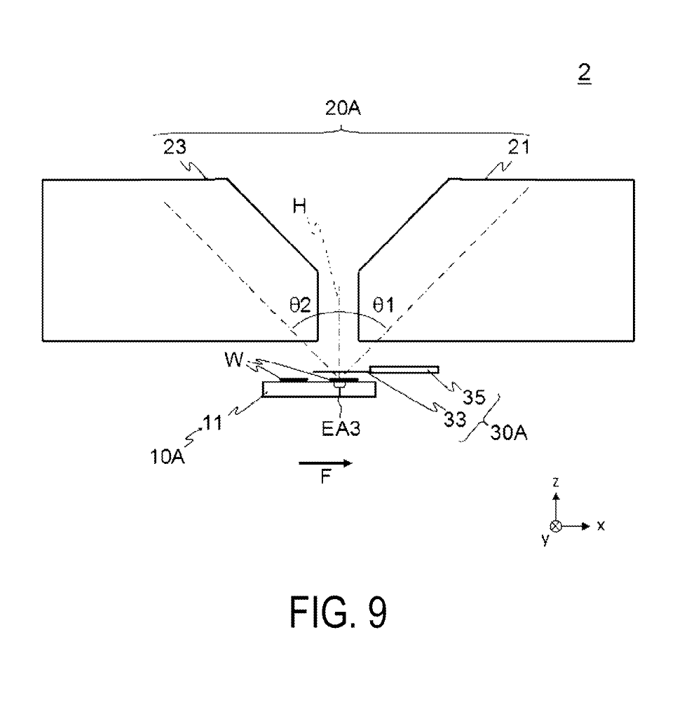

FIG. 9 is a schematic front view of the polarized light radiation device 2 according to a second embodiment. The polarized light radiation device 2 includes mainly a transport unit 10A configured to transport the substrate W, a light radiation unit 20A configured to emits exposure light, and a mask unit 30A.

The transport unit 10A mainly includes a stage 11, a horizontal drive unit 12a configured to move the stage 11 in the horizontal direction (see FIG. 4), and a position detection unit 13 configured to measure the position of the stage 11 (see FIG. 4).

The light radiation unit 20A is configured to radiate light onto the substrate W, and includes two light radiation units 21 and 23. The light radiation unit 23 has an identical configuration to the configuration of the light radiation unit 21, and is provided so as to face the light radiation unit 21.

The P-polarized light having transmitted through the PBS 216 of the light radiation unit 21 enters at an incident angle θ1 that ranges from approximately 50° to approximately 70°. The P-polarized light having transmitted through the PBS 216 of the light radiation unit 23 enters at an incident angle θ2 that also ranges from approximately 50° to approximately 70°. The incident angle θ1 and the incident angle θ2 are surface symmetrical with respect to a plane that includes the line H and that is substantially orthogonal to the x direction.

The mask unit 30A is provided on the optical paths of the light radiated onto the substrate W from the light radiation units 21 and 23. When polarized light is radiated onto the substrate W from the light radiation units 21 and 23, the mask unit 30A and the top surface 11a are contiguous to each other.

The mask unit 30A mainly includes a mask 33 and a mask holding unit 35. The mask 33 is a substantially plate-like member having a substantially rectangular shape in plan view. The mask 33 is held substantially parallel to the top surface 11a by the mask holding unit 35. In addition, the mask 33 is driven in the x direction, the y direction, the z direction, and the θ direction by the mask holding unit 35.

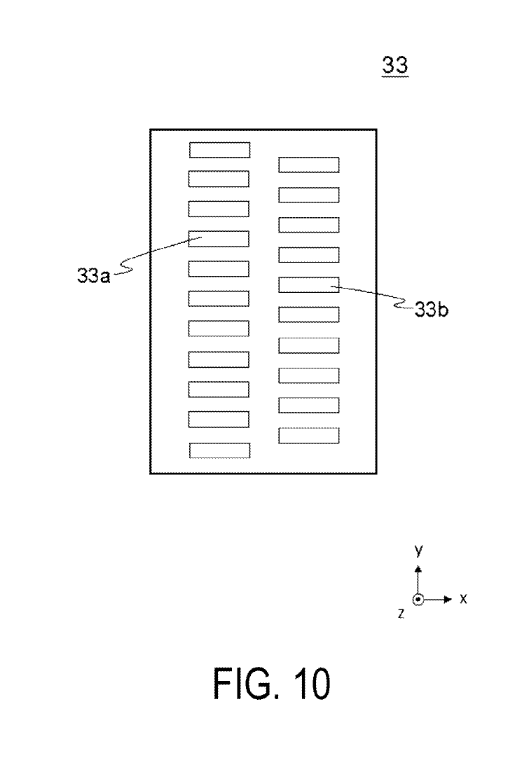

FIG. 10 is a diagram illustrating a light transmission region formed in the mask 33. The mask 33 includes band-like light transmission regions 33a and 33b each of which extends in the x direction.

A plurality of light transmission regions 33a are arranged in line along the y direction and so are a plurality of light transmission regions 33b. In addition, the light transmission regions 33a and the light transmission regions 33b are disposed in a staggered manner so that none of the light transmission regions 33a is disposed at a position that overlaps the position of any of the light transmission regions 33 in the x direction or in the y direction.

Next, the operations of the polarized light radiation device 2 configured as described above will be described with reference to FIG. 9. The drive control unit 101b makes the horizontal drive unit 12a move the stage 11 along the transport direction F (in the +x direction). When the position determination unit 101c determines that the substrate W1 is about to enter a region to be irradiated with the P-polarized light from the light radiation units 21 and 23 (i.e., light-irradiated region EA3), the light source control unit 101a turns on the lamps 211a of the light radiation units 21 and 23. Then, with the lamps 211a kept in that state, the drive control unit 101b moves the stage 11 in the transport direction F. As a result, the light radiated by the light radiation units 21 and 23 is continuously radiated onto the substrate W.

Of the P-polarized light from the light radiation unit 21, the light that has passed through the light transmission region 33a is first radiated onto the substrate W1, and is then radiated onto the substrates W2 and W3. Likewise, of the P-polarized light from the light radiation unit 23, the light that has passed through the light transmission region 33b is first radiated onto the substrate W1, and is then radiated onto the substrates W2 and W3.

The regions irradiated with the polarized light that has passed through the light transmission region 33a (i.e., regions III, not illustrated) and the regions irradiated with the polarized light that has passed through the light transmission region 33b (i.e., regions IV, not illustrated) are band-like regions each of which extends along the transport direction F. The regions III correspond to the regions I, and the regions IV correspond to regions II. The regions III and IV are formed alternately along the y direction and contiguously to each other.

When the position determination unit 101c determines that the substrates W2 and W3 have traveled past the light-irradiated region EA3, the light source control unit 101a turns off the lamps 211a of the light radiation units 21 and 23. Then, with the lamps 211a kept in that state, the drive control unit 101b moves the stage 11 in the transport direction F. Thereafter, the control unit 101 terminates the series of processes.

According to the present embodiment, polarized light can be radiated from different directions in a single exposure process. Thus, the regions III and IV may be formed simultaneously in a single exposure process. In addition, because each of the incident angles θ1 and 02 ranges from approximately 50° to approximately 70°, an alignment film can be produced through the photoalignment process so that the liquid crystal molecules have a small pre-tilt angle.

Embodiments of the invention have been described in detail with reference to the drawings. However, specific configurations are not limited to the embodiments, and changes in the design or the like are also included within a scope which does not depart from the gist of the invention.

Further, the term “substantially” in the present invention is not to be understood as merely being strictly the same, and is a concept that includes variations and modifications to an extent that does not result in loss in identity. For example, a term “substantially parallel” and a term “substantially orthogonal” are not limited to “strictly parallel” and “strictly orthogonal”. In addition, for example, terms such as “parallel”, “orthogonal”, and the like include “substantially parallel”, “substantially orthogonal”, and the like, respectively. To put it differently, those terms are not strictly limited to the parallel state, orthogonal state, and the like, respectively. In addition, the term “proximity” is used in the present invention to mean a concept where, for example, a place in the proximity of a certain point A may include the point A or otherwise as long as the place is near the point A.

### REFERENCE SIGNS LIST

1, 2 Polarized light radiation device
10, 10A Transport unit
11 Stage
11a Top surface
12 Driving unit
12a Horizontal drive unit
12b Rotary driving unit
13 Position detection unit
20, 20A Light radiation unit
21, 22, 23 Light radiation unit
30, 30A Mask unit
32, 33 Mask
32a, 33a, 33b Light transmission region
32b Light blocking region
35 Mask holding unit
100 Pixel region
101 Control unit
101a Light source control unit
101b Drive control unit
101c Position determination unit
102 Storage unit
103 Input section
104 Output section
211 Light source
211a Lamp
211b Reflective mirror
212, 213 Mirror
214 Fly-eye lens
215 Condenser lens
216 PBS

1. A polarized light radiation device comprising:
a light source that emits polarized light;
a mask having a light transmission region formed therein, the light transmission region allowing polarized light having been emitted from the light source to pass therethrough; and
a stage on which an exposure target object to be irradiated with polarized light having passed through the light transmission region is placed,
wherein the light source radiates polarized light onto the exposure target object from a direction inclined by approximately 50° to approximately 70° in relation to a direction that is substantially orthogonal to a top surface of the stage.

2. The polarized light radiation device according to claim 1 further comprising a drive unit that moves the stage in a transport direction and rotate the stage by approximately 180°,
wherein the light source includes a first light source and a second light source that are arranged along the transport direction,
the drive unit rotates the stage by approximately 180° between the first light source and the second light source,
the mask includes:
a first mask having a first light transmission region formed therein, the first light transmission region allowing exposure light having been emitted from the first light source to pass therethrough; and
a second mask having a second light transmission region formed therein, the second light transmission region allowing exposure light having been emitted from the second light source to pass therethrough, and
the second light transmission region is formed at a position to allow light to be radiated onto a region in the exposure target object, the region being not irradiated with any light having passed through the first light transmission region.

3. A polarized light radiation method comprising the step of emitting light from a direction inclined by approximately 50° to approximately 70° in relation to a direction that is substantially orthogonal to a top surface of a stage on which an exposure target object is placed, the light being emitted while the stage being transported in a transport direction.

4. A polarized light radiation method comprising the steps of:
transporting, in a transport direction, a stage on which an exposure target object is placed;
with the stage having been transported to a first position, emitting light from a direction inclined by approximately 50° to approximately 70° in relation to a direction that is substantially orthogonal to a top surface of the stage and radiating the light onto a first region of the exposure target object while the stage is being transported in the transport direction;
transporting the stage in the transport direction to a second position;
with the stage having been transported to the second position, rotating the stage by approximately 180°;
transporting the stage in the transport direction to a third position; and
with the stage having been transported to the third position, emitting light from a direction inclined by approximately 50° to approximately 70° in relation to a direction that is substantially orthogonal to the top surface of the stage and radiating the light onto a second region of the exposure target object while the stage is being transported in the transport direction, the second region being different from the first region of the exposure target object.
